(19) United States
(12) Patent Application Publication
(10) Pub. No.: US 2015/0168565 A1
(43) Pub. Date: Jun. 18, 2015

(54) CARBON NANOMATERIALS BASED REAL TIME RADIATION DOSIMETER

(71) Applicant: UNIVERSITÀ DEGLI STUDI DI SALERNO, Fisciano SA (IT)

(72) Inventors: Claudia Altavilla, Fisciano (IT); Paolo Ciambelli, Fisciano (IT); Maria Funaro, Fisciano (IT); Antonio Proto, Fisciano (IT); Maria Sarno, Fisciano (IT)

(73) Assignee: UNIVERSITÀ DEGLI STUDI DI SALERNO, FISCIANO (IT)

(21) Appl. No.: 14/414,424

(22) PCT Filed: Jul. 11, 2013
(86) PCT No.: PCT/IB2013/055706

§ 371 Date: Jan. 12, 2015

(30) Foreign Application Priority Data
Jul. 12, 2012 (IT) SA2012A000011

(51) Int. Cl. G01T 1/14; G01T 1/185; G01T 1/02; C23C 16/26

(52) U.S. Cl. CPC G01T 1/14; C23C 16/26; G01T 1/185; G01T 1/026

(57) ABSTRACT

A real time radiation dosimeter includes a first electrode and a second electrode, such as cathode and anode electrodes. The second electrode is based on carbon nanomaterials, such as carbon nanotubes bucky paper, carbon nanotubes forest and graphene film. The dosimeter is connected to an electrometer, able to apply a bias voltage between the electrodes and to measure the collected charge. The manufactured detectors display an excellent linear response to dose. The dosimeter with nanotubes forest is able to collect charge also to zero voltage, allowing in vivo applications. The use of nanomaterials allows a miniaturized version of dosimeters.

### FIELD OF THE INVENTION

The invention relates to a real time radiation dosimeter having electrodes based on carbon nanomaterials, such as carbon nanotubes bucky paper, carbon nanotubes forest and graphene film.

In the present description the definition of carbon nanomaterials is used generically to mean carbon based nanostructured materials.

The invention further relates to a method of producing these electrodes.

### DESCRIPTION OF THE PRIOR ART

The clinical use of ionizing radiation to obtain a necrosing or cytotoxic radiobiological effect on tumoral lesions requires wide and complex physical and dosimetrical procedures. In particularly, it is necessary to calculate accurately the absorbed dose optimizing its delivery in order to treat the tumor saving the surrounding healthy tissues. Delivery parameters of a prescribed dose are determined during treatment planning which is performed on dedicated computers using specialized treatment planning software. It is crucial to ensure that the prescribed dose is exactly equal to that delivered by the accelerator.

Over the last few decades, various radiation dosimeters have been utilized for the quantification of the absorbed dose and in the quality assurance programs, such us ionizing chambers, radiographic and radiochromic films, thermoluminescence dosimeters (TLDs), semiconductor silicon diodes, metal-oxide-semiconductor field effect transistor (MOSFET) dosimeters.

Radiographic film have 2D spatial resolution but they are sensitive to light, require a chemical processing and their response depends on the energy. These problems are solved in radiochromic dosimeters, although their response in not linear with dose. Moreover, they do not allow to realize real time measurement and they require a complex calibration. TLDs presents some advantages such as response with a low dependence on photon energy and linear response for a wide dose interval, low cost, small size and the possibility to perform in vivo measurements. The advantages of TLDs include sensitivity to environmental conditions, fading due to temperature or light effects and the impossibility to realize real time measurements. Semiconductor silicon diodes have the advantage of small physical size and they can be used for in vivo application but need of several correction factors for even simple use in clinical radiotherapy and their response depends on temperature. MOSFET dosimeters overcome the correction factors required for diodes and they can be used for the measurement of delivered dose in patient, but they are expensive and they destroy after few treatments.

The above dosimeters have a feature in common: they are only suitable for relative dosimetry on the contrary of ionization chambers which allow absolute measurements of dose. They are characterized by high accuracy, practicality and reliability, but they require a high bias voltage to achieve an acceptable collection of charges and have a relative large physical size which limits their spatial resolution. These drawbacks limit their application for in vivo dose measurements.

Thus, there is the need to provide improved electrodes for an ionization chamber and a method to produce them, wherein the ionization chamber may have bigger spatial resolution and may be operated at a small voltage.

Patent Pub. No. US 2010/0193695 A1 (Pub. Date Aug. 5, 2010) proposes a dosimeter with a singular element or multiple sensing elements that are arrayed in 1-D, 2-D and 3-D formations. Each sensing element is made up of two electrodes with carbon materials deposited between the electrodes. As regards carbon materials, carbon powder, carbon fibers, carbon nanoparticles and carbon nanotubes are developed. In the present proposal, indeed, the geometry of the dosimeter is completely different and more simple. The electrodes are based on carbon nanomaterials: no material is deposited between the electrodes. Also the materials are different: electrodes with carbon nanotubes bucky paper, carbon nanotubes forest and graphene film are developed and a description of the method to produce them is furnished. Moreover, in Patent Pub. No. US 2010/0193695 no measurements of collected charges are performed at different bias voltages and in particular also to zero bias voltage, excluding the possible use for in vivo applications.

Patent Pub. No. US 2010/0253359 A1 (Pub. Date Oct. 7, 2010) proposes a ionization chamber for sensing molecule particles, comprising an electrode including a substrate having a first material and a plurality of nanowires extending form the substrate and a further electrode facing the first one. Also in this case, the geometry and the materials are different. Moreover, no experimental result is reported in some application field and in particular no application in the field of dosimetry is proposed.

Patent Pub. No. WO 2004/059298 A1 (Pub. Date Jul. 15, 2004) proposes a miniaturized gas sensor which includes two electrodes. One of the electrodes is a carbon nanotube film having a carbon nanotube density such that the film behaves as a conducting sheet electrode. The carbon nanotubes are vertically aligned toward the opposite electrode. Also in this case the geometry and the materials are different. In the present proposal, a bucky paper of randomly carbon nanotubes, a forest of vertically aligned carbon nanotubes and a graphene film are developed. Moreover, the sensor of Pub. No. WO 2004/059298 is proposed for gas detection and not as a radiation dosimeter.

### BRIEF DESCRIPTION OF THE DRAWINGS

FIG. 1a-c are schematic views of the proposed radiation detector.

FIG. 2 is an illustration of the experimental set up for testing the present invention.

FIG. 3a is a schematic view of the radiation detector with silicon-MWCNTs anode and aluminium cathode.

FIG. 3b is a schematic view of silicon-MWCNTs electrode.

FIG. 4 is the TEM image of NiFe2O4 nanoparticles prepared by a “wet chemistry” approach.

FIG. 5a-c are the SEM images of vertically aligned carbon nanotubes grown by CCVD on silicon substrate at different magnification.

FIG. 5d is the SEM image of a patterned substrate (d).

FIG. 6 is a graphic illustration of the collected charge at 310 V as a function of the dose for ionizing chamber with silicon-MWCNTs anode and aluminium cathode at a distance of 12 mm.

FIG. 7 is a graphic illustration of the collected charge at 105 MU as a function of bias voltage for ionizing chamber with silicon-MWCNTs anode and aluminium cathode at a distance of 12 mm.

FIG. 8 is a graphic illustration of the collected charge at 0 V as a function of the dose for ionizing chamber with silicon-MWCNTs anode and aluminium cathode at a distance of 6 mm (blue indicators). It shows also the collected charge at 0 V and 105 MU for the same device with a distance between the electrodes equal to 12 mm (red indicator).

FIG. 9a is a schematic view of radiation detector with copper-graphene anode and aluminium cathode.

FIG. 9b is a schematic view of copper-graphene electrode.

FIG. 10 is a graphic illustration of the collected charge at 310 V as a function of the dose for ionizing chamber with copper-graphene anode and aluminium cathode at a distance of 12 mm.

### DETAILED DESCRIPTION OF THE INVENTION

Thus, there may be a need to provide an improved electrode for an ionization chamber and a method producing it, wherein the ionization chamber has a bigger spatial resolution and may be operated at a small voltage.

In order to meet the need defined above, real time radiation dosimeters with electrodes based on carbon nanomaterials, such as carbon nanotubes bucky paper, carbon nanotubes forest and graphene film, and a method of producing the electrodes are provided.

A ionizing chamber, in its simplest form, consists of two metallic plates separated by a distance D. The gap D is filled with a gas or noble liquid. A bias voltage is applied to maintain a uniform electric field between the electrodes. When ionizing radiation interacts with the gas or the noble liquid, ion-electron pairs are created. Under the electric field, positive ions and electrons drift in opposite directions toward the anode and chatode, respectively, where the charge produced by ionizing particles is collected.

For the conventional ionization chamber, the electrodes usually contain a several millimeters thick plastic covered with conductive materials, such as aluminium or graphite coated Mylar®.

The advantages of radiation dosimeters with carbon nanomaterials based electrodes can be summarized as follows: i) the thickness of the electrode is much smaller than its planar geometry; consequently the dosimeter offers good spatial resolution; ii) the atomic number of carbon material is 6, which could be regarded as tissue equivalent; therefore carbon nanomaterials dosimeter are characterized by an excellent linear response on radiation dose; iii) carbon nanomaterials have extremely desirable properties of high mechanical and thermal stability, high thermal conductivity, and unique electrical properties such as large current carrying capacity. So, they allow a better charge collection efficiency of conventional ionization chambers and subsequently the possibility to operate at smaller bias voltages; iv) carbon nanomaterials radiation dosimeters are economical and their fabrication process is simple.

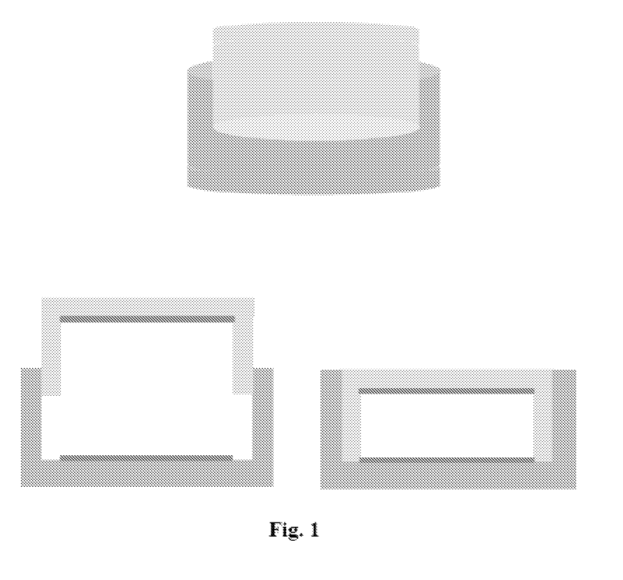

The two electrodes of each chamber were held by the basis of a cylindrical plastic container (FIG. 1). The gap between the two electrodes can be filled with a gas or a liquid. The separation between the electrodes can be varied from 0.2 mm to 50 mm.

The radiation is one of x-ray beams, electron beams and photon beams.

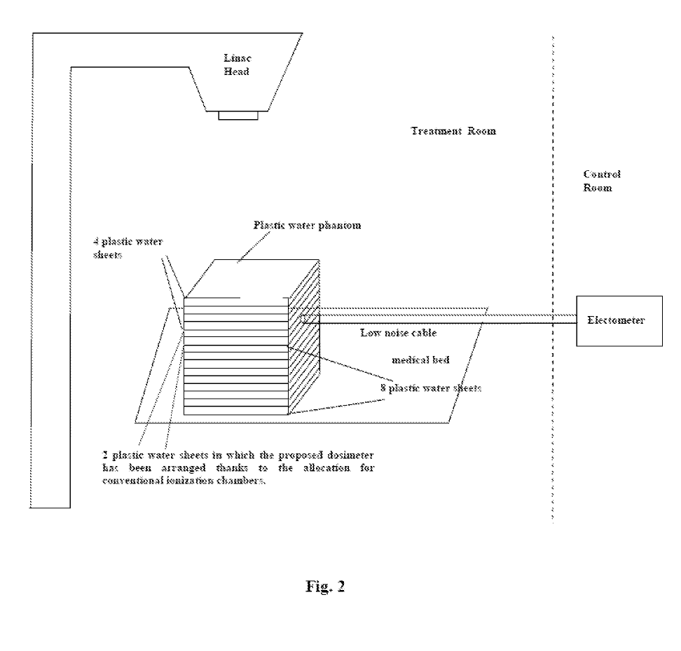

An electrometer, connected to the electrodes via a low noise cable (FIG. 2), applies a bias voltage, in the range form 0 V to 500 V, and it reads the collected charge.

The method of manufacturing carbon nanotubes bucky paper based electrodes, comprises:

A synthesis of Multiwalled Carbon Nanotubes (MWCNTs) by hydrocarbon (methane, ethylene, acetylene, propylene) catalytic chemical vapour deposition (CCVD), on transition metal supported catalysts (Co, Fe, Ni on SiO2, Al2O3, MgO), following the steps listed below:
1. The catalyst is prepared by impregnation of SiO₂, Al₂O₃, MgO powder with Co—Fe—Ni salts in ethanol solution;
2. for the MWCNTs synthesis a mixture of hydrocarbon in N₂ or H₂ (10%-30% v/v) is fed to a continuous flow reactor at temperatures between 873 and 1073 K and a runtime between 10 and 60 min. Gas flow rate and catalyst mass are 120 (stp)cm³/min and 400 mg;
3. to remove catalyst impurities, the grown MWCNTs are treated with 46% HF aqueous solution; the solid residue is afterwards extracted and washed with distilled water, then centrifuged and finally dried at 353 K for 12 h.
   The MWCNTs are used to fabricate a thin films following the steps reported below:
1. a sonication of a suspension of MWCNTs in presence of a surfactant.
2. a vacuum filtration of the solution onto a polycarbonate or nylon membrane support.
   After drying, films of different thickness and densities are removed from the support; the thickness, orientation and density of CNTs in the films are easily controllable.

The method of manufacturing carbon nanotubes forest based electrodes, comprises: i) the synthesis of ferrite nanoparticles (MFe2O4 where M=Fe, Co, Ni); ii) pattering of the nanoparticles on suitable substrate of silicon, metal or dielectric by microcontact printing; iii) catalytic chemical vapour deposition (CCVD) growth of carbon nanotubes.

The method of manufacturing graphene films based electrodes comprises the fabrication of few-layer graphene films on suitable substrate of silicon, metal or dielectric by CCVD.

### EXAMPLE 1

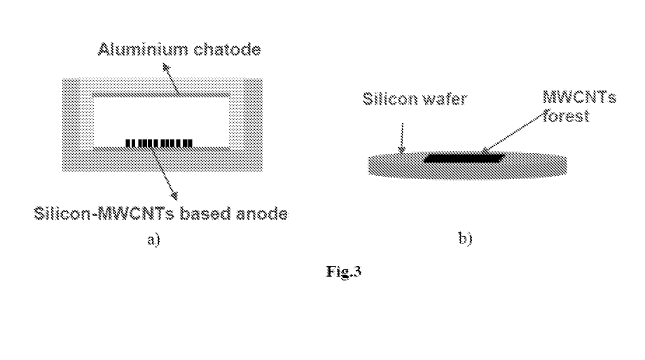

In the first example, a ionization chamber, comprising an aluminium cathode and a carbon nanotubes forest based anode, is proposed as dosimeter (FIG. 3). In particular, a forest of vertically aligned MWCNTs were grown by CCVD on a silicon substrate.

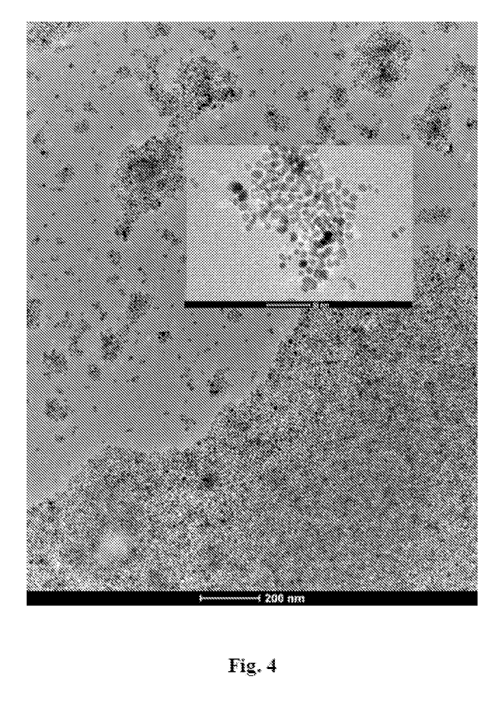

To synthesise MWCNTs, nichel ferrite nanoparticles NiFe₂O₄ were first prepared by a wet chemistry approach (FIG. 4). In particular, Ni(acac)₂ (1 mmol), Fe(acac)₃ (1 mmol), 1.2 hexadecanediol (10 mmol), oleic acid (6 mmol), oleylamine (6 mmol), and phenyl ether (20 mL) were mixed and magnetically stirred under nitrogen flow. The mixture was heated to 265° C. for 30 min. Then, the black-brown mixture was cooled to room temperature and ethanol was added under ambient condition; the black material was precipitated and separated via centrifugation. The products were dispersed in hexane and stored in a vial.

The nanoparticles, dispersed in hexane, were patterned by microcontact printing using a PDMS stamp on silicon wafer SiO₂/Si.

The silicon substrate was mounted into a vertical quartz tube reactor and maintained at room temperature under N₂ flow (80 (stp)cm³/min) for 4 min. The reactor was then introduced in a pre-heated furnace at 800° C. for 10 min under a N₂ atmosphere. After replacing the pure N₂ flow by a gas mixture of C₂H₄ (purity 99.998%, flow rate 8 (stp)cm³/min) in N₂ (purity 99.999% pure, flow rate 72 (stp)cm³/min), the reactor was maintained at 800° C. for 10 min. The reactor was then cooled to room temperature under a N₂ flow.

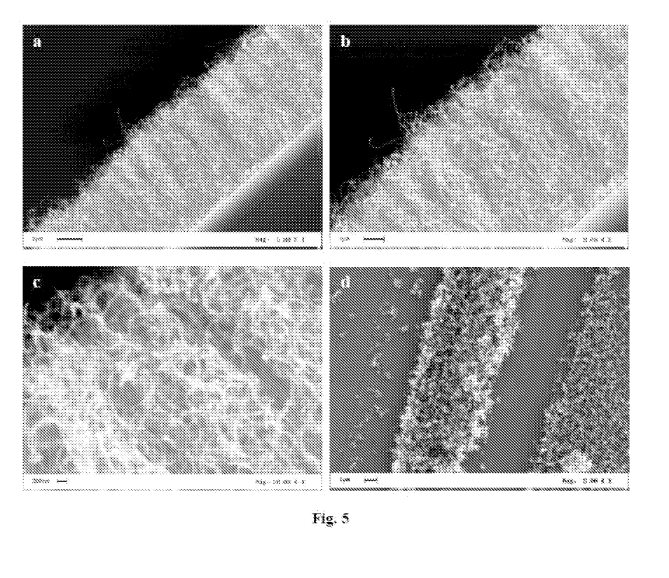

In FIG. 5 the cross section of a silicon wafer after CCVD synthesis is shown. The formation of vertically aligned CNT forest on substrate is clearly observed. The thickness of CNT film is ≈12 μm.

The above dosimeter was exposed to the 6 MeV photon beam generated by a LINAC (Precise Elekta) used for daily hospital radiotherapy. It was placed in a tissue-equivalent phantom on the central part of a 10×10 cm² irradiation field at a distance between its centre and the source equal to 100.0 ±0.2 cm (FIG. 2).

The above dosimeter was irradiated at room temperature under atmospheric pressure with radiation dose corresponding to 21 Monitor Units (MU), 50 MU and 105 MU. In the used irradiation experimental set-up, 1 MU corresponds to 95.3 cGy

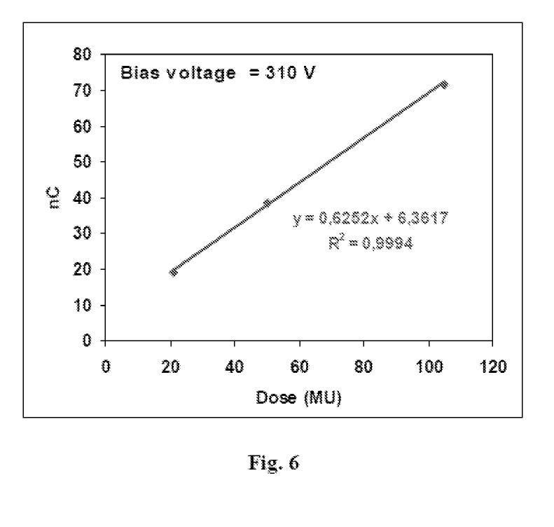

A bias voltage of 310 V was applied between the electrodes which were distant 12 mm. The collected charge shows an excellent linear dependence on dose. (FIG. 6). Linear response is a necessary characteristic for an efficient dosimeter.

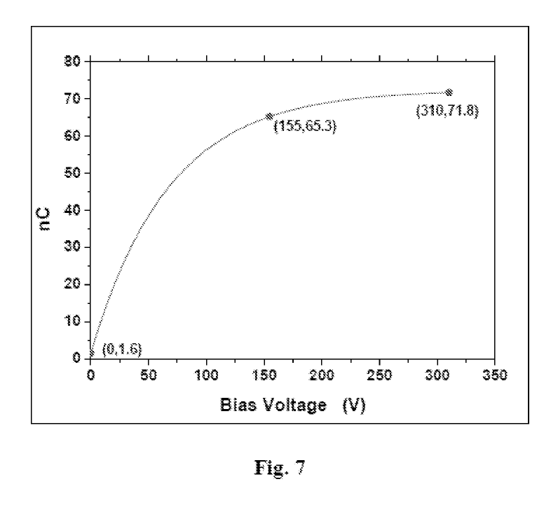

Measurements of the collected charge were also performed at three different bias voltages equal to 0 V, 155 V and 310 Vat the same radiation dose of 105 MU and at distance between the electrodes of 12 mm. The collected charge shows an exponential dependence on bias voltage (FIG. 7). Surprisingly, the collected charge is different form zero at no bias voltage. By increasing the bias voltage, the electric field between the electrodes becomes stronger and the detector is able to collect more charge, until a plateau is reached.

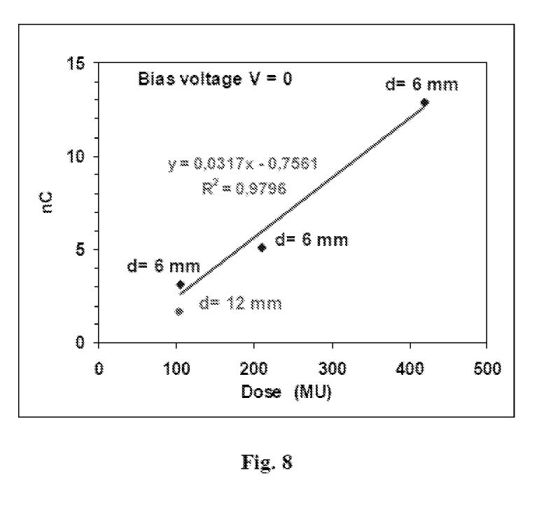

Measurements of the collected charge were also performed at a distance between the electrodes equal to 6 mm and a bias voltage of 0 V. The detector was irradiated with 105 MU, 210 MU and 420 MU. Also in this case the collected charge shows a linear response on dose (FIG. 8). Halving the electrodes distance has the effect to double the collected charge (FIG. 8).

### EXAMPLE 2

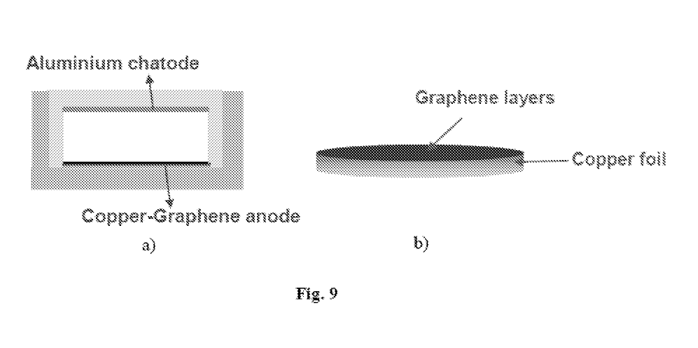

In the second example, the proposed dosimeter is a ionization chamber comprising an aluminium cathode and graphene layers based anode (FIG. 9).

Graphene layers were prepared on 25 μm copper foil by CCVD of methane diluted in nitrogen.

The synthesis was performed in isothermal conditions at 950° C., 100 (stp)cm³/min flow rate, after 40 min pre-treatment of the foil from room temperature up to the synthesis temperature. The average cooling rate after the synthesis was 2° C./min.

The experimental irradiation set-up was as in example 1 (FIG. 2).

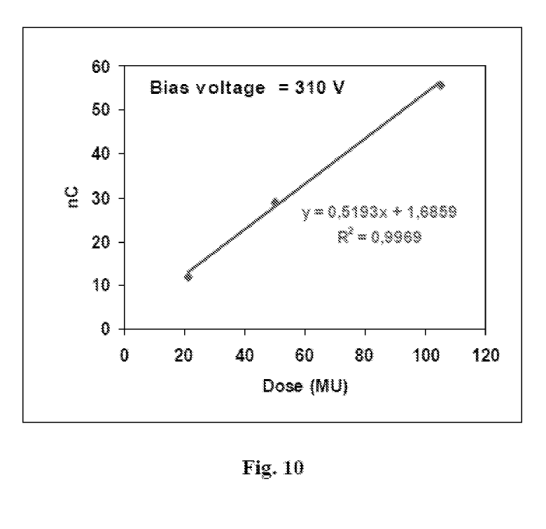

The dosimeter was irradiated with 21 MU, 50 MU and 105 MU. A bias voltage of 310 V was applied between the electrodes which were distant 12 mm. Also in this case, the collected charge shows an excellent linear dependence on dose (FIG. 10).

1. A detection device for radiation, comprising an ionization chamber having:
a first electrode and a second electrode, positioned in such a way as to be facing each other;
an electrometer able to apply a bias voltage between the electrodes and to measure the collected charge,
said device being characterized in that said second electrode comprises a carbon based nanostructured material.

2. The detection device for radiation according to claim 1, wherein said carbon based nanostructured material includes carbon nanotubes bucky paper and/or carbon nanotubes forest.

3. The detection device for radiation according to claim 1, wherein said carbon based nanostructured material comprises a graphene layer.

4. The detection device for radiation according to claim 1, wherein said second electrode has a substrate of silicon, dielectric or metallic material, for supporting said carbon based nanostructured material.

5. The detection device for radiation according to claim 1, wherein said first electrode comprises a sheet of metal or metal alloy.

6. The detection device for radiation according to claim 1, wherein said said first electrode and said second electrode respectively function as a cathode and anode of said ionization chamber.

7. The detection device for radiation according to claim 1, wherein said “bucky paper” includes a plurality of carbon nanotubes oriented in a random way.

8. The detection device for radiation according to claim 1, wherein said forest comprises a plurality of multi-walled carbon nanotubes and vertically aligned to the first electrode.

9. The detection device for radiation according to claim 1, wherein the distance between the electrodes varies from 0.2 mm to 50 mm.

10. The detection device for radiation according to claim 1, wherein a space between said first and said second electrode comprises gaseous or liquid phase material.

11. The detection device for radiation according to claim 1, wherein the voltage value of “bias” between the electrodes is in the range from 0 V to 500 V.

12. The detection device for radiation according to claim 1, wherein the measurement of the charge collected at said ionization chamber has a linear dependence on the dose of radiation that invests the device itself, said dependence being linear type also in correspondence of values of the radiation dose very low, for example of the order of cGy.

13. The detection device for radiation according to claim 1, wherein the measurement of the charge collected at said ionization chamber is different from zero even in the absence of a voltage application of “bias”, allowing in vivo applications.

14. The detection device for radiation according to claim 1, wherein said detected radiation is one of x-ray beams, electron beams and photon beams.

15. Method for the production of a detection device for radiation according to claim 1, comprising the steps of:
providing an ionization chamber having a first and a second electrode positioned in such a way as to be facing each other;
connecting an electrometer to said ionization chamber, said electrometer being adapted to apply a voltage of “bias” between said first and second electrode and to measure the charge collected in correspondence of said first and second electrode, characterized in that a deposition step of a carbon based nanostructured material is performed on a surface of said second electrode, in particular on the surface facing said first electrode.

16. The method according to claim 15, wherein said deposition step comprises the realization of “bucky paper” carbon nanotubes.

17. The method according to claim 16, wherein said realization of “bucky paper” comprises a step of synthesis of multi-walled carbon nanotubes (MWCNT) by chemical vapor deposition assisted by catalyst (CCVD) of hydrocarbons on catalysts supported by metals transition.

18. The method according to claim 17, wherein said hydrocarbon is selected from the group comprising: methane, ethylene, acetylene, propylene.

19. The method according to claim 17, comprising a step of sonication of a suspension of said multi-walled carbon nanotubes (MWCNT), in presence of a surfactant.

20. The method according to claim 19, wherein said sonication is followed by a step of vacuum filtration of a solution obtained on a membrane support, such as polycarbonate or nylon, for the realization of a film.

21. The method according to claim 15, wherein said deposition step comprises the development of carbon nanotubes forests.

22. The method according to claim 21, wherein said development of carbon nanotubes forests comprises the steps of:
synthesis of ferrite (MFe2O4) nanoparticles;
“patterning” of said nanoparticles on suitable substrates of silicon, dielectric or metallic material, by means of microcontact printing;
growing by chemical vapor deposition assisted by catalyst (CCVD) of carbon nanotubes.

23. The method according to claim 15, wherein said deposition step comprises the development of a graphene layer.

24. The method according to claim 23, wherein said development of a graphene layer comprises: the preparation of graphene layers on suitable substrates of silicon, dielectric or metallic material by chemical vapor deposition assisted by catalyst (CCVD).
